(19) United States
(12) Patent Application Publication
(10) Pub. No.: US 2006/0001557 A1
(43) Pub. Date: Jan. 5, 2006

(54) Computer-implemented method for compressing image files

(75) Inventor: Hong Liao, Nanning City (CN)

Correspondence Address: CARSTENS & CAHOON, LLP, P O BOX 802334, DALLAS, TX, 75380, US

(73) Assignee: Tom Dong SHIANG, Nanning City (CN)

(21) Appl. No.: 10/995,576

(22) Filed: Nov. 23, 2004

(30) Foreign Application Priority Data
Nov. 24, 2003 (CN) 2003101114618

(51) Int. Cl. H03M 7/00

(52) U.S. Cl. 341/60

(57) ABSTRACT

The present invention discloses a computer-implemented method for compressing bi-level image files, during the computer-implemented process, said bi-level image files are to be compressed with the algorithm comprising following steps: abstracting symbols from the bi-level image files and re-sorting the symbols, and symbol encoding. The present compression method is based on symbols instead of pixels, the compression ratio of this algorithm is improved by 50% compared to the PDG format by BJSDCX, and is improved by more than 30%, compared to the NLC format by National Library. It is suitable for compression and management for archive files.

### TECHNICAL FIELD

This invention relates to a computer-implemented method for processing image data, especially to a computer-implemented method for compressing bi-level image files.

### BACKGROUND OF THE INVENTION

According to <Key IT Application Programs of the Tenth Five-year Plan of the National Economy and Social Development> issued at the end of 2002 by the PRC Government, it is defined clearly that information resource is the kernel for IT applications, therefore, how to digitalize hard copy archive files becomes a common and key difficulty in IT applications, wherein the compression of digitalized materials is the bottleneck of said difficulty. A compression algorithm of high-efficiency and high-quality helps to reduce the storage cost, improve the transmission speed over the net and the decompression speed for display when the material is to be shared.

The existing commonly used bi-level image method is an important technology in the management of digital files. It has the advantages such as: what you see is what you get, no errors, direct view and convenient for use, high-speed and high-efficiency, etc., therefore, it is widely used for processing and searching service in digital libraries, digital archives and professional databases, such as patent database, etc., where, the compression ratio of the image format adopted is an important technical index. Currently, the worldwide popular file formats use the compression algorithm of TIFF G4 stimulated by CCITT. Of course, there are some other file formats, e.g., PDG format, which is developed by Beijing Shi Dai Chao Xing (BJSDCX) Company and used in the largest national internet commercial digital library having more than 500,000 e-books, and NLC format, which is developed by China National Library having more than 100,000 e-books. Both of the formats use a compression algorithm slightly superior than TIFF G4, and the image files can be compressed at a rather good compression ratio, however, there is still much room for improving the compression ratio. Take an example of a digital file for an A4 size page with scanning resolution of 300 DPI, the average size of the file in PDG format is around 45 KB, while the average size of the file in NLC format is around 35 KB.

Most of the current image files are bi-level bitmap files, and the commonly used bi-level bitmap compression methods are pixel-based. In a comparison between different compression methods, it is found that, in the compression of bi-level archive files, the compression ratio of PDG format developed by BJSDCX company is similar to that of the TIFF G4 standard, while the compression ratio of NLC format developed by China National Library is similar to that of the CCITT T.82 Standard, namely JBIG1 standard. JBIG is the English Abbreviation of Joint Bi-level Image Experts Group, which was set up in 1988, having the task of establishing the international standard for bi-level image compression. And images are compressed based on image pixels for both of TIFF G4 and JBIG1. With the pixel-based compression method, pixels of images are processed according to the scanning sequences, and each pixel is encoded one by one from top to bottom, and from left to right. In TIFF G4, improved Huffman encoding is used, namely, to encode the number of continuous black pixels or white pixels by Huffman encoding. In JBIG1, each pixel is encoded using adaptive arithmetical encoding, and the probability statistic model of the arithmetical encoding is determined by the values of certain amount of and certain structure of templates prior to the pixel being encoded. Since both of the compression methods are pixel-based, it is difficult to further improve the compression ratio.

In fact, most of the bi-level archive files consist of large areas of white background and large amount of repeated characters, e.g., in an archive file consisting of Chinese characters, a lot of Chinese characters and interpunctions will appear repeatedly, which is a typical feature for bi-level archive files. If a compression method can take advantage of this feature, the compression ratio will be greatly improved compared to those pixel-based compression methods.

### SUMMARY OF THE INVENTION

The main object of the present invention is to provide a computer-implemented method for compressing image files, so as to overcome the shortcomings of the above mentioned methods, take advantage of said feature of the bi-level image files, and further improve the compression ratio.

The present invention involves a computer and bi-level image files, during the computer-implemented process, said bi-level image files are to be compressed with the algorithm comprising following steps:
a) abstracting symbols from the bi-level image files, so as to obtain an array for symbols;
b) re-sorting the abstracted symbols according to the read/write sequence of the symbols, so as to obtain a new array for re-sorted symbols;
c) processing the re-sorted symbols one by one, the current symbol being processed is compared with the representative symbols in a dictionary, wherein said dictionary consists of representative symbols which are renewed and encoded dynamically;
wherein, during the comparison, if a representative symbol in the dictionary is found matching with the current symbol, then, encoding the feature information of the current symbol, said feature information including the dimension, position and index of the current symbol;
during the comparison, if no representative symbol in the dictionary is found matching with the current symbol, then, adding the current symbol into the dictionary as a new representative symbol, and the index of said new representative symbol is set as a specific integer; then, encoding the feature information of the current symbol;
d) returning to step c) to process the next symbol, until all re-sorted symbols are processed, and finally both of the encoding data of pixels of all representative symbols in the dictionary and the encoding data of the feature information of all symbols in the bi-level image files are obtained.

The present invention also provides a computer program product, said software product disposed on a computer readable medium comprising instructions for causing a computer to implement the above-mentioned steps for compressing bi-level image files.

The above mentioned compression method is based on symbols of the image files instead of on pixels, and the compression ratio is greatly improved compared to that of PDG format by BJSDCX and that of NLC format by National Library, which is well illustrated by following test result.

A comparison test is conducted for compressing three samples of image files produced by graphical material digitalization production line, using this algorithm, PDG format by BJSDCX, and NLC format by National Library respectively, and the result is shown in the table below:

| | | | | | Improving ratio |
|---|---|---|---|---|---|
| | | | Improving ratio of | | of this algorithm |
| | This | PDG format | this algorithm to | NLC format | to NLC format by |
| | algorithm | by BJSDCX | PDG format by | by National | National Library |
| file name | (KB) | (KB) | BJSDCX (%) | Library (KB) | (%) |
| 000019 | 25.90 | 64.10 | 59.59 | 50.90 | 49.12 |
| 000025 | 15.20 | 29.10 | 47.77 | 21.70 | 29.95 |
| 000031 | 25.80 | 48.10 | 46.36 | 34.30 | 24.78 |
| average | 22.30 | 47.10 | 51.24 | 35.63 | 34.61 |

All of the above files being tested are bi-level files of A4 size with scanning resolution of 300 DPI. As shown in FIGS. 4-6, all of the three files attached in the figures are printed after being processed with this algorithm. It can be seen from the above statistics, the compression ratio of this algorithm is improved by 50% compared to the PDG format by BJSDCX, and is improved at a considerable ratio, by more than 30%, compared to the NLC format by National Library.

### BRIEF DESCRIPTION OF THE DRAWINGS

FIG. 1 is the flow diagram of the compression algorithm according to the present invention;

FIG. 2 is the schematic layout of ten pixels;

FIG. 3 is the schematic diagram showing the normalization within the encoding intervals;

FIG. 4-FIG. 6 show the image files printed after being processed with the compression algorithm of the present invention.

### DETAILED DESCRIPTION OF THE PREFERRED EMBODIMENTS

The present invention will be described in details in combination with the accompanying figures.

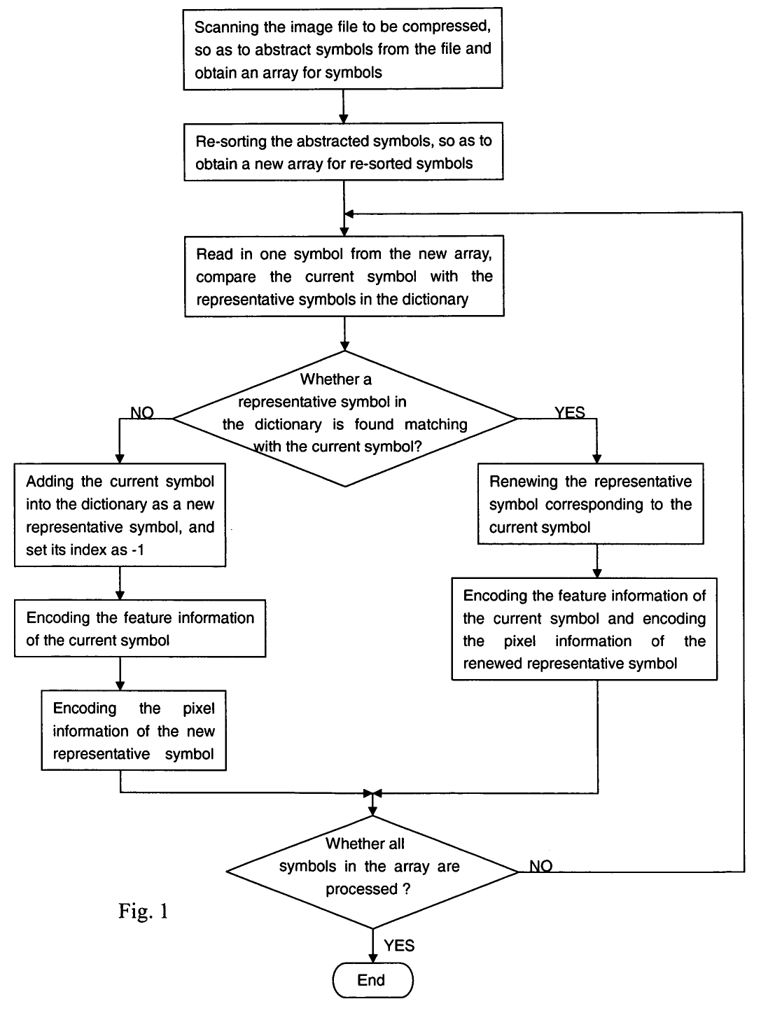

As shown in the flow diagram of the compression algorithm of the present invention of FIG. 1, the present compression algorithm comprises two parts including symbol abstraction and re-sorting, and symbol encoding. In the first part, symbols are abstracted from the bitmap and re-sorted; while in the second part, symbols abstracted are encoded. The detailed description is as follows:

Abstraction and Re-Sorting of Symbols

1. Symbol Abstraction

The symbols are abstracted from the bitmap using the conventional edge tracking method and area-filling method. Furthermore, we need to abstract some important features of the symbols, e.g., centroid, area, etc., which play an important role in symbol comparison and symbol classification.

Symbol abstraction normally includes two phases, wherein, at the first phase, the symbol is processed with edge tracking method, so as to obtain the position information of the edge pixels of the current symbol. When the tracking begins, first, the bitmap is scanned from left to right, and from top to bottom. The first black pixel found is used as the initial point of the current tracking, then, following this point, the position information of each edge point is recorded along the edge of the current symbol, until returning to the initial point. In this algorithm, we use 8-neighborhood method, i.e., searching the next boundary point from the 8 neighborhood points of the current boundary point. The average compression ratio can be improved by around 1% using 8-neighborhood method compared to 4-neighborhood method.

The second phase is area-filling, i.e., to fill the area surrounded by the boundary points obtained from the first phase with the background color (white color), so as to abstract the area surrounded by the boundary points from the bitmap as a symbol. Meanwhile, at this phase, the array information of the pixels of the symbol is also recorded.

Pursuant to the symbol abstraction, the features of the symbols are to be obtained: the area of the symbol can be obtained by multiplying the length and the width of the rectangular frame surrounding the boundary points; the average distance between each black pixel of the symbol to the left boundary of the rectangular frame surrounding the boundary points is the position of the centroid of the symbol. At this time, the position information, feature information and pixel information of a symbol can be added to the array of the symbol.

2. Symbol Re-Sorting

At this phase, the symbols are re-sorted according to the read/write sequence of the symbols. This step will bring great benefits to the next compression step, because when recording the position coordinates (hereafter refer to the rectangular coordinates) of the symbols, what we recorded is the offset of the position of the current symbol relative to the previous encoded symbol, if the symbols are sorted according to the read/write sequence of the symbols, and the symbols are encoded according to this sequence, the offset of position between the sequential symbols will be minimum, thus, the code will be shortest for encoding.

The process at this phase can be divided into following steps:

Calculating the slope angle, row space and symbol space of the bitmap.

Dividing the symbols into groups according to the area where they are located.

Re-sorting the symbols, so that, the symbols re-sorted will meet following conditions: within the area, the symbols are allocated in sequence from top to bottom, and from left to right; and the areas are allocated in the sequence according to the Y value of the center point of the area, the area having smaller Y value is at a former position, and the area having larger Y value is at the later position.

In calculation of the slope angle of the bitmap, the document frequency method is used. For each symbol, n symbols closest to it are chosen, wherein, n is normally equal to 10. Calculate respectively the included angle between the horizontal line and the line connecting the centroid of each of the n symbols with the centroid of the target symbol. Thus, if we abstract N symbols from the bitmap, we can obtain n*N angular values from the above calculation. Next, the histogram is made for these angular values, wherein, the precision of the X-coordinate of the histogram is set as 1/1800. Then, smoothing the histogram with Hamming Window, wherein the mathematic expression of the Hamming Window is: 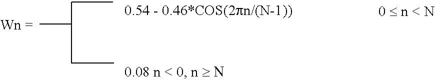
and wherein, N=10. Make convolution calculation with the Hamming Window and the histogram, the angular value corresponding to the maximum convolution parameter obtained is the slope angle of the bitmap.

Similarly, we calculate the length of the connection lines between the centroid of each symbol and the centroid of each of the closest n symbols. The row space is calculated with the lengths of all connection lines falling within ±30 angular degrees relative to vertical line, wherein, it should be noted that, when calculating the included angles between the connection lines and the vertical line, the slope angle of the bitmap should be taken into consideration, i.e., the calculation result of the previous step should be counted. Similar to the calculation of the angles, we should make histogram of these lengths, then, smooth the histogram with the rectangular window, the mathematic expression of the rectangular window is: 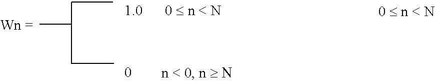
and wherein, N=10. Make convolution calculation with the rectangular window and the histogram, the length corresponding to the maximum convolution result is the row space of the symbols.

With the same method, we can get the symbol space, except that, when choosing inter-symbol connection lines, all those falling within ±30 angular degrees relative to the horizontal line are chosen for calculation.

Both of the above-mentioned Hamming Window and rectangular window are smooth filters.

At the bitmap, if we connect the centroid of each symbol with the centroids of its n neighborhoods, we can see that the whole bitmap becomes a network with the symbols as its nodes. If we cut all lines whose length is longer than three times of the row space, then, the whole bitmap becomes several sub-networks, each sub-network being an area of the original bitmap. We conclude the symbols of each sub-network into one group, thus, the bitmap is divided into areas.

After area division, the symbols should be re-sorted. First, the center point of each area of the bitmap is calculated, and the areas are sorted in ascending sequence according to the value of the Y coordinates of the center points; then, the symbols within the areas are sorted in sequence from top to bottom, and from left to right. In sorting the symbols within the areas, we use Howard method: first to allocate lines, then to sort the symbols within the lines. First, we sort the symbols in ascending sequence according to the Y-coordinates of their bottom boundaries, then, we make a base line using the average value of the Y coordinates of the bottom boundaries of the most front N symbols, and compare the top boundaries of all symbols with this base line. Any symbol whose top boundary is higher than this base line is regarded in the same line with the previous N symbols. For the remaining symbols, we allocate the lines with the same method. After the line allocation is completed, the symbols in the same line are sorted in ascending sequence according to the X-coordinates of the left top boundary of the symbols.

Up to now, we have abstracted the symbols from the bitmap, and sorted the symbols according to the read/write sequence. Next, we will set up a dictionary for the symbols. Said dictionary consists of symbols obtained by following method: when compressing a bitmap with this algorithm, first to scan the whole bitmap, then, to abstract the symbols constructed by inter-connected black pixels. In the same bitmap, some symbols will appear repeatedly, e.g., a coma “,”. We conclude all similar symbols determined by our similarity rules into one group, choose one symbol as the representative of this group, and the collection of the representative symbols of all symbol groups becomes the dictionary.

The dictionary is set up dynamically during the compression, new symbols will be added to the dictionary during the compression, wherein the existing dictionary refers to the dictionary which is set up dynamically during the compression. In the beginning of the compression, the dictionary is empty, when the first symbol is read in from the symbol array, it is added to the dictionary; afterwards, whenever a new symbol is read in, it is compared with the symbols in the existing dictionary, if the comparison result is similar, the new symbol will not be added to the dictionary, otherwise, the new symbol is added to the dictionary.

(II) Symbol Encoding

During the symbol encoding, the symbol dictionary is set up dynamically, meanwhile, the symbols are compressed and encoded; the dictionary is set up dynamically, and synchronously with the compression of the symbols. The set up of the dictionary needs an effective symbol similarity decision method. The encoding course of the symbols is illustrated as follows:
for each symbol in the new array
   making symbol similarity decision, searching the matching symbol in the dictionary
   if the matching symbol is found in the dictionary
   encoding the index of the symbol in the dictionary
   encoding the coordinate information (the coordinate difference with the previous symbol) of the current symbol in the image file
   encoding the dimension (length, width) information of the current symbol
   else
   encoding the bitmap data of the current symbol directly
   encoding the index of the current symbol in the dictionary, wherein the index is −1
   encoding the coordinate information (the coordinate difference with the previous symbol) of the current symbol in the image file
   encoding the dimension (length-width) information of the current symbol
   adding the current symbol into the dictionary
   end if
end for

The process involves several key technologies such as: symbol similarity decision, bitmap data encoding, and integer encoding for the index and position and dimension information of the symbols. These three technologies will be described respectively as follows.

1. Symbol Similarity Decision

In order to set up the dictionary, the most important step is to make accurate judgment for the similarity of the symbols. When comparing two symbols, the centroids of the two symbols should be coincided, then, compare the pixels of the two symbols, and make judgment according to the pre-set judgment rules and threshold values, so as to determine whether the two symbols are matched. The symbols match with each other can be included in the same group, and the average of group members is set in the dictionary as the representative symbol of this group. During compression, all members of the group can be represented by the index of the representative symbol in the dictionary.

During similarity decision, the dimensions of the two symbols are compared first, if the length difference or width difference of the two symbols is larger than two pixels, the two symbols are regarded non-matching. If the dimensions of the two symbols are in conformity with the requirements, it is necessary to further compare the pixels of the two symbols.

In comparing the pixels of the two symbols, first the centroids of the two symbols are coincided, then the pixels of the two symbols are compared one by one, and an error diagram is set up for the two symbols. The size of the error diagram is the size when the centroids of the two symbols are coincided, the positions of the black pixels of the error diagram are the positions where the two pixels are of different color. After the error diagram is obtained, following check and decision should be conducted to the error diagram:

If it is found the four pixels within the 2×2 neighborhoods are all of black, the two symbols are determined as non-matching.

Checking the 8 neighborhoods of each black pixel in the error diagram, if it is found there are at least two black dots among the 8 neighborhoods of a certain black pixel (the error pixel A hereafter referred to as ERROR-A), and at least two black dots are not connected, then it is necessary to check the pixels of the two symbols in the original bitmaps (hereafter referred to as ORIGNAL1_A and ORIGNAL2_A) corresponding to the ERROR_A in the error diagram. If in the 8 neighborhoods of ORIGNAL1_A and ORIGNAL2_A, all of the 8 neighborhood pixels are of the same color, then it is determined that the two symbols are non-matching. If the length and the width of the two symbols are less than 12 pixels, then, if in the 8 neighborhoods of ORIGNAL1_A and ORIGNAL2_A, at least 4 of the 8 neighborhood pixels are of the same color, then it is determined that the two symbols are non-matching.

Calculate the total amount of the black pixels in the error diagram, and make the total amount divided by the area of the error diagram, if the result is larger than a pre-set threshold value, then, the two symbols are determined as non-matching. In this algorithm, the threshold value is set as 0.25.

When processing a new symbol, the first step is to search the best match in the set dictionary. If the matching symbol of this symbol can be found in the dictionary, then, the symbol is added to the group in the dynamic dictionary represented by the corresponding symbol. If no matching symbol is found in the dictionary, then, this symbol is added to the dynamic dictionary as the representative symbol of a new symbol group. The simplest method for setting up a dynamic dictionary is to list the first symbol which has no matching symbols in the dictionary as a new item in the dictionary. However, in consideration of such symbol may be a relative poor representative of its kind, which will directly affect the compression ratio and decompression quality, we renew the symbol in the dictionary during the dynamic setting up of the dictionary. If the current processing symbol has no matching symbol in the dictionary, this symbol will be added to the dynamic dictionary. If a matching symbol is found, the corresponding symbol in the dictionary will be renewed, and the renewed symbol is the average result of all symbols of the represented group. The course of making average may cause such result: after averaging all the symbols of the group, some symbols of the group may be no longer matched with the symbol in the dictionary. Therefore, after the new dictionary is set up, the relationship between each item of the dictionary with the corresponding symbol group will be re-checked. If non-matching symbols are found, the found item will be included in the dictionary as a new item. However, such situation seldom occurs, according to our experiments, the probability is only around 2%.

2. Bitmap Data Encoding

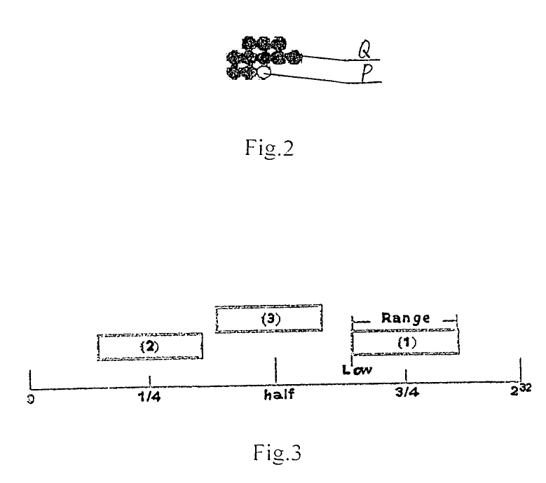

If no matching symbols can be found in the dictionary, the index of this symbol will be set as −1, and the symbol should be added in the dynamic dictionary. When encoding this symbol, in addition to encoding the position, length, width and index of the symbol, the pixels of the symbol should be compressed and encoded. The information such as the position and index of the symbol is compressed with integer encoding method, which will be described in the subsequent content. The pixels of the dictionary symbols are compressed with the context-based bi-level adaptive arithmetical encoding method of low precision. In this algorithm, we use the context template of JBIG compression algorithm, wherein the pixels Q are distributed at the current line of and the two upper lines above the pixel P being encoded, there are totally 10 pixels as shown in FIG. 2.

There are totally 1024 kinds of permutation and combination variations for the 10 bi-level pixels, therefore, two arrays should be created, each including 1024 integer items. These two arrays are used to record the occurrence Count_{—}1 for black pixels, and the occurrence Count_{—}0 for white pixels. Both of these two arrays are initialized as 0, and during the compression, whenever one black pixel occurs, Count_{—}1 is added by 1, otherwise, Count_{—}0 is added by 1. When the sum of Count_{—}1 and Count_{—}0 is more than 255, both of Count_{—}1 and Count_{—}0 should be divided by 2 respectively.

With the probability information provided by the statistic model, the bi-level arithmetical encoding method of low precision is used for encoding. The precision of the encoding register used in this algorithm is 32 bits. The bi-level arithmetical encoding method is to represent the occurrence probability of 0 or 1 as a sub-interval of one interval, the ratio between the sub-interval to the whole interval is the occurrence probability of the signal (0 or 1) being encoded, then, this sub-interval will become the current encoding interval, when encoding for the next signal, a sub-sub-interval corresponding to the occurrence probability of the encoding signal is further divided within the new encoding interval. When the interval is less than a pre-set value, the encoding interval should be normalized, and the encoding bits are output according to the situation. These steps are repeated, until all of the signals are encoded. The encoding course will be described below with Pseudo-code. Here, we use LPS (Less Probable Symbol) to represent the input bits which occur at low probability, and we use MPS (More Probable Symbol) to represent the input bits which occur at high probability. Count_{—}0 represents the occurrence of 0, Count_{—}1 represents the occurrence of 1, Range represents the encoding interval, Low represents the left boundary of encoding interval. At the initial of the encoding, Range is set as ½×2³²-1, and Low is set as 0.

```
If ( Count_0 < Count_1 =
  {
LPS=0 ;
Count_LPS= Count_0 ;
  }
else
  {
LPS=1 ;
Count_LPS= Count_1 ;
  }
Range_LPS= Range*Count_LPS/(Count_0 +Count_1) ;
If (Current_Inputting_Bit=LPS)
  {
Low+= Range − Range_LPS ;
  }
else
  {
Range − = Range_LPS ;
  }
```

When the encoding interval is less than ¼ of 2³², the Range should be normalized, and the encoding bits are output.

FIG. 3 illustrates three kinds of situations for normalization at the coding intervals. When the coding interval is less than ¼ of 2³², if the left boundary Low is larger than ½ of 2³² as shown in situation (1), one encoding bit 1 is output, Low is deducted by half; if it is under situation (2), encoding bit 0 is output; if it is under situation (3), there will be no output, but a counter is used for counting, whenever situation (3) occurs, the counter will be added by 1, next time, when situation (1) or situation (3) is met and encoding bit is to be output, encoding bits of the same number as the value in the counter are output, at this time, the value of the output encoding bits is opposite to that under situation (1) or situation (2). Finally, no matter at what kind of situation, Both of the values of Range and Low should be doubled. The above steps are repeated until the value of Range is larger than ¼ of 2³². The image pixels are compressed and encoded, with ⅓ of data compressed.

3. Integer Encoding

After the compression of the dictionary symbols, all symbols should be encoded and compressed based on the dictionary symbols. In encoding, we only need the index information and position information of the current encoding symbol in the dynamic dictionary. The position information is the relative coordinates of the current encoding symbol relative to the previous encoding symbol, namely, the differential value between the left bottom coordinate of the circumscribed rectangular frame of the current symbol and the right bottom coordinate of the circumscribed rectangular frame of the previous encoding symbol. All these values are integers. In compression, we use the integer encoding method based on the tree structure.

The integer encoding process includes following three steps: first to encode the sign bit of the integer, then, to encode the bits necessary for storing the integer with uni-encoding method, finally, to encode the integer itself. For example, the code for the integer 9 is 0 0001 1001, and the code for the integer −9 is 1 0001 1001.

The coder sets up the judgment tree according to the bits to be encoded. The judgment tree branches at the node, forwards to the left node or the right node according to the current encoding. The root node of the judgment tree is corresponding to the sign bit, if the integer is a positive number, the code is 0, if it is a negative number, the code is 1. When encoding a certain bit, the probability information of the encoding node corresponding to the bit is renewed in the meantime, said probability information records the occurrence frequency of 0 or 1. The frequency information and the current encoding bit can be further encoded using the arithmetical coder which is described in the previous paragraph, so as to obtain a relatively good compression ratio. After the encoding of a certain bit is finished, the next sub-node is forwarded according to whether the current encoding bit is 0 or 1, the next bit is then encoded, until all bits are encoded.

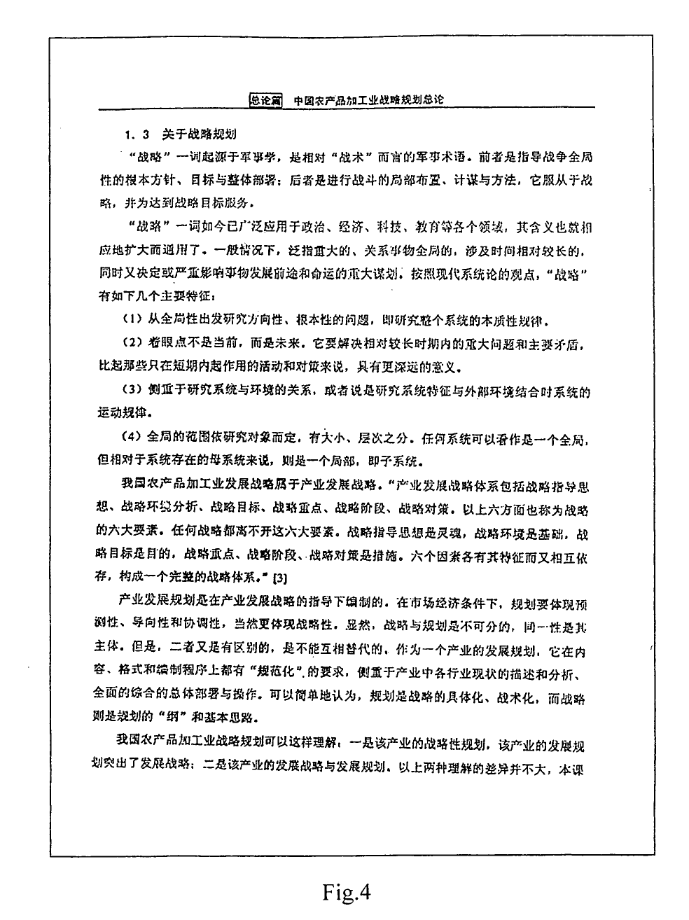

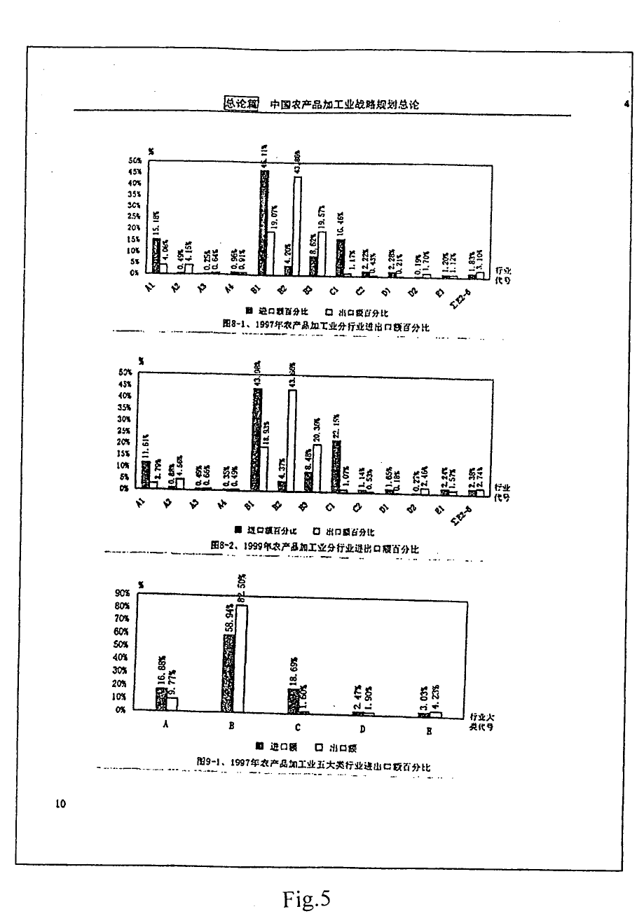

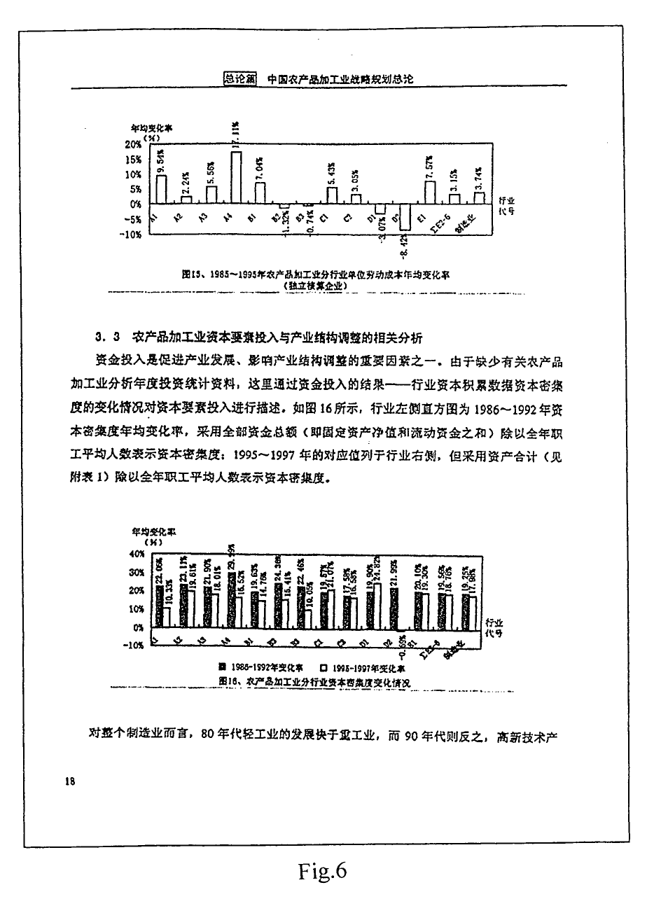

FIG. 4-6 shows the graphic files printed after processed with this compression algorithm, wherein, FIG. 4 is text, FIG. 5 is graph, and FIG. 6 is a combination of text and graph. Seen from the three copies of the files, the printed files are clear and lossless compared to the original copies. Therefore, this algorithm is practical and economical.

Actually, most of the bi-level archive files consist of white background and large quantity of repeated symbols, e.g., in a digital archive file, the comma and the full stop will appear repeatedly. Take advantage of this feature, the repeated symbols can be concluded in one group, while only one representative symbol is needed for each group. When compressing the bitmap data (pixels), only the representative symbol is compressed, while for other symbols of the group, only the position information (X-coordinate and Y-coordinate) and the index relative to the representative symbol are needed to be stored for decompression. For example, if there are 50 commas in a digital archive file, we only need to store the pixel information of one comma, for other 49 commas, only the index relative to the first comma in the dictionary is necessary. Compared with the pixel-based image compression method, it is not necessary to store each pixel of the digital archive file, therefore, the compression ratio is greatly improved.

The present method is computer-implemented, at the beginning of the compression, computer programs enable the image files to be read into the internal storage from the hard disk or other storage media, then, all computing work during the compression is completed under the control of the CPU of the computer.

What is claimed is:

1. A computer-implemented method for compressing bi-level image files, said bi-level image files are to be compressed with the algorithm comprising following steps:
a) abstracting symbols from the bi-level image files, so as to obtain an array for symbols;
b) re-sorting the abstracted symbols according to the read/write sequence of the symbols, so as to obtain a new array for re-sorted symbols;
c) processing the re-sorted symbols one by one, the current symbol being processed is compared with the representative symbols in a dictionary, wherein said dictionary consists of representative symbols which are renewed and encoded dynamically;
wherein, during the comparison, if a representative symbol in the dictionary is found matching with the current symbol, then, encoding the feature information of the current symbol, said feature information including the dimension, position and index of the current symbol;
during the comparison, if no representative symbol in the dictionary is found matching with the current symbol, then, adding the current symbol into the dictionary as a new representative symbol, and the index of said new representative symbol is set as a specific integer; then, encoding the feature information of the current symbol;
d) returning to step c) to process the next symbol, until all re-sorted symbols are processed, and finally both of the encoding data of pixels of all representative symbols in the dictionary and the encoding data of the feature information of all symbols in the bi-level image files are obtained.

2. A computer-implemented method for compressing bi-level image files according to claim 1, wherein, during step c), if a representative symbol in the dictionary is found matching with the current symbol, then, renewing the representative symbol by averaging all members in the group represented by said representative symbol, and then, encoding the pixels of the renewed representative symbol and encoding the feature information of the current symbol.

3. A computer-implemented method for compressing bi-level image files according to claim 1, wherein, during step c), if no representative symbol in the dictionary is found matching with the current symbol, then, adding the current symbol into the dictionary as a new representative symbol, and the index of the representative symbol is set as “−1”.

4. A computer-implemented method for compressing bi-level image files according to claim 1, wherein, during step a), the process of abstracting symbols including following two phases:
(1) edge tracking: the current symbol is processed with conventional edge tracking method, so as to obtain the position information of the edge pixels of the current symbol;
(2) area filling: to fill the area surrounded by the boundary points obtained from said first phase with the background color, so as to abstract the area surrounded by the boundary points from the bitmap as a symbol; and the array information of the pixels of the symbol is also recorded.

5. A computer-implemented method for compressing bi-level image files according to claim 1, wherein, during step b), the re-sorting of symbols includes following three steps:
(1) calculating the slope angle, row space and symbol space of the bitmap, wherein, said slope angle is calculated with the following mathematic expression: 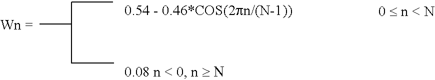
wherein, N is the number of the symbols abstracted from said bitmap, and n is the number of the closest symbols for each symbol;
(2) dividing the symbols into groups according to the area where they are located;
(3) re-sorting the symbols, so that, the symbols re-sorted will meet following conditions: within the area, the symbols are allocated in sequence from top to bottom, and from left to right; and the areas are allocated in the sequence according to the Y value of the center point of the area, the area having smaller Y value is at a former position, and the area having larger Y value is at the later position.

6. A computer-implemented method for compressing bi-level image files according to claim 3, wherein, the process of step c) can be expressed as follows:
for each symbol in the new array
making symbol similarity decision, searching the matching symbol in the dictionary
if the matching symbol is found in the dictionary
encoding the index of the symbol in the dictionary
encoding the coordinate information (the coordinate difference with the previous symbol) of the current symbol in the image file
encoding the dimension (length, width) information of the current symbol
else
encoding the bitmap data of the current symbol directly
encoding the index of the current symbol in the dictionary, wherein the index is −1
encoding the coordinate information (the coordinate difference with the previous symbol) of the current symbol in the image file
encoding the dimension information of the current symbol
adding the current symbol into the dictionary
end if end for
wherein, said process involves several key technologies such as: symbol similarity decision, bitmap data encoding, and integer encoding.

7. A computer-implemented method for compressing bi-level image files according to claim 6, wherein, said symbol similarity decision includes following steps:
(1) comparing the dimension of the two symbols: if the length difference or width difference of the two symbols is larger than two pixels, the two symbols are regarded non-matching; if the dimensions of the two symbols are in conformity with the requirements, it is necessary to further compare the pixels of the two symbols;
(2) comparing the pixels of the two symbols: first the centroids of the two symbols are coincided, then the pixels of the two symbols are compared one by one, and an error diagram is set up for the two symbols.

8. A computer-implemented method for compressing bi-level image files according to claim 6, wherein, said bitmap data encoding includes:
with the probability information provided by the statistic model, the bi-level arithmetical encoding method of low precision is used for encoding, wherein, the precision of the encoding register used in this algorithm is 32 bits;
said bi-level arithmetical encoding method is to represent the occurrence probability of 0 or 1 as a sub-interval of one interval, the ratio between the sub-interval to the whole interval is the occurrence probability of the signal (0 or 1) being encoded, then, this sub-interval will become the current encoding interval, when encoding for the next signal, a sub-sub-interval corresponding to the occurrence probability of the encoding signal is further divided within the new encoding interval;
when the interval is less than a pre-set value, the encoding interval should be normalized, and the encoding bits are output according to the situation;
these steps are repeated, until all of the signals are encoded.

9. A computer-implemented method for compressing bi-level image files according to claim 6, wherein, said integer encoding includes following steps:
(1) encoding the sign bit of the integer;
(2) encoding the bits necessary for storing the integer with uni-encoding method;
(3) encoding the integer itself.

10. A computer program product for compressing bi-level image files, said software product disposed on a computer readable medium comprising instructions for causing a computer to:
a) abstracting symbols from the bi-level image files, so as to obtain an array for symbols;
b) re-sorting the abstracted symbols according to the read/write sequence of the symbols, so as to obtain a new array for re-sorted symbols;
c) processing the re-sorted symbols one by one, the current symbol being processed is compared with the representative symbols in a dictionary, wherein said dictionary consists of representative symbols which are renewed and encoded dynamically;
wherein, during the comparison, if a representative symbol in the dictionary is found matching with the current symbol, then, encoding the feature information of the current symbol, said feature information including the dimension, position and index of the current symbol;
during the comparison, if no representative symbol in the dictionary is found matching with the current symbol, then, adding the current symbol into the dictionary as a new representative symbol, and the index of said new representative symbol is set as a specific integer; then, encoding the feature information of the current symbol;
d) returning to step c) to process the next symbol, until all re-sorted symbols are processed, and finally both of the encoding data of all representative symbols in the dictionary and the encoding data of the feature information of all symbols in the bi-level image files are obtained.

11. A computer program product for compressing bi-level image files according to claim 10, wherein, during step c), if a representative symbol in the dictionary is found matching with the current symbol, then, renewing the representative symbol by averaging all members in the group represented by said representative symbol, and then, encoding the pixels of the renewed representative symbol and encoding the feature information of the current symbol.

12. A computer program product for compressing bi-level image files according to claim 10, wherein, during step c), if no representative symbol in the dictionary is found matching with the current symbol, then, adding the current symbol into the dictionary as a new representative symbol, and the index of the representative symbol is set as “−1”.

13. A computer program product for compressing bi-level image files according to claim 10, wherein, during step a), the process of abstracting symbols including following two phases:
(1) edge tracking: the current symbol is processed with conventional edge tracking method, so as to obtain the position information of the edge pixels of the current symbol;
(2) area filling: to fill the area surrounded by the boundary points obtained from said first phase with the background color, so as to abstract the area surrounded by the boundary points from the bitmap as a symbol; and the array information of the pixels of the symbol is also recorded.

14. A computer program product for compressing bi-level image files according to claim 10, wherein, during step b), the re-sorting of symbols includes following three steps:
(1) calculating the slope angle, row space and symbol space of the bitmap, wherein, said slope angle is calculated with the following mathematic expression: 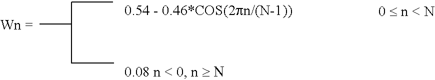
wherein, N is the number of the symbols abstracted from said bitmap, and n is the number of the closest symbols for each symbol;
(2) dividing the symbols into groups according to the area where they are located;
re-sorting the symbols, so that, the symbols re-sorted will meet following conditions: within the area, the symbols are allocated in sequence from top to bottom, and from left to right; and the areas are allocated in the sequence according to the Y value of the center point of the area, the area having smaller Y value is at a former position, and the area having larger Y value is at the later position.

15. A computer program product for compressing bi-level image files according to claim 12, wherein, the process of step c) can be expressed as follows:
for each symbol in the new array
making symbol similarity decision, searching the matching symbol in the dictionary
if the matching symbol is found in the dictionary
encoding the index of the symbol in the dictionary
encoding the coordinate information (the coordinate difference with the previous symbol) of the current symbol in the image file
encoding the dimension (length, width) information of the current symbol
else
encoding the bitmap data of the current symbol directly
encoding the index of the current symbol in the dictionary, wherein the index is −1
encoding the coordinate information (the coordinate difference with the previous symbol) of the current symbol in the image file
encoding the dimension information of the current symbol
adding the current symbol into the dictionary
end if
end for
wherein, said process involves several key technologies such as:
symbol similarity decision, bitmap data encoding, and integer encoding.

16. A computer program product for compressing bi-level image files according to claim 15, wherein, said symbol similarity decision includes following steps:
(1) comparing the dimension of the two symbols: if the length difference or width difference of the two symbols is larger than two pixels, the two symbols are regarded non-matching; if the dimensions of the two symbols are in conformity with the requirements, it is necessary to further compare the pixels of the two symbols;
(2) comparing the pixels of the two symbols: first the centroids of the two symbols are coincided, then the pixels of the two symbols are compared one by one, and an error diagram is set up for the two symbols.

17. A computer program product for compressing bi-level image files according to claim 15, wherein, said bitmap data encoding includes:
with the probability information provided by the statistic model, the bi-level arithmetical encoding method of low precision is used for encoding, wherein, the precision of the encoding register used in this algorithm is 32 bits;
said bi-level arithmetical encoding method is to represent the occurrence probability of 0 or 1 as a sub-interval of one interval, the ratio between the sub-interval to the whole interval is the occurrence probability of the signal (0 or 1) being encoded, then, this sub-interval will become the current encoding interval, when encoding for the next signal, a sub-sub-interval corresponding to the occurrence probability of the encoding signal is further divided within the new encoding interval;
when the interval is less than a pre-set value, the encoding interval should be normalized, and the encoding bits are output according to the situation;
these steps are repeated, until all of the signals are encoded.

18. A computer program product for compressing bi-level image files according to claim 15, wherein, said integer encoding includes following steps:
(1) encoding the sign bit of the integer;
(2) encoding the bits necessary for storing the integer with uni-encoding method;
(3) encoding the integer itself.
